(19) United States
(12) Patent Application Publication
(10) Pub. No.: US 2011/0245964 A1
(43) Pub. Date: Oct. 6, 2011

(54) Self Aligning Automated Material Handling System

(76) Inventors: Robert P. Sullivan, Wilmington, MA (US); Michael L. Bufano, Belmont, MA (US)

(21) Appl. No.: 12/754,699

(22) Filed: Apr. 6, 2010

(51) Int. Cl. H01L 21/677; H01L 21/683

(52) U.S. Cl. 700/228

(57) ABSTRACT

A semiconductor workpiece processing system comprises at least one processing tool; a transport section configured to transport carriers to and from the processing tool; and a transport vehicle movably mounted on the transport section; wherein the transport vehicle is configured to: sense a location of a transport carrier alignment feature; adjust a location of a transport vehicle gripper based on the location of the transport carrier alignment feature; sense an attitude of the gripper at a point of engagement with the transport carrier; and adjust the location of the gripper based on the attitude of the gripper.

### BACKGROUND

1. Field

The exemplary embodiments relate to an automated material handling system and, more particularly, to an automated material handling system for semiconductor workpieces.

2. Brief Description of Related Developments

The initial alignment of conventional automated material handling systems (“AMHS”) for semiconductor transport carriers, such as for example, FOUPs and SMIFs is typically performed to account for variations in the placement and alignment of tool load ports in a fab. These conventional AMHS use separate fixtures and external sensors during the alignment process. These fixtures are placed on the load port to begin the teaching process and require constant operator interaction so that the proper alignment between the AMHS transport vehicle and the load port is achieved. Teaching a load port position to for example, a transport vehicle of the AMHS, includes teaching the X-axis, Y-axis, Z-axis and theta angle of the transport vehicle gripper to properly pick or place a payload, such as a transport carrier from or to the load port.

In addition, during the initial alignment external sensors are used for optical measurements relative to a fiducial or similar reference feature to detect the proximity of the gripper to the reference feature. The reference feature has a known or assumed offset relative to a pick or place position. The use of these external sensors and separate fixtures make the initial alignment and any subsequent alignments cumbersome, labor intensive and time consuming.

### SUMMARY

The present disclosure provides a method of performing alignment in a material handling system. The method comprises moving a gripper of a transport vehicle towards to a transport carrier; sensing a location of an alignment feature on the transport carrier; adjusting a location of the gripper based on the location of the alignment feature; and storing the location of the gripper in a memory of the automated material handling system.

Implementations of the disclosure may include one or more of the following features. In some implementations, the method includes comprises sensing an attitude of the gripper at a point of engagement between the gripper and the transport carrier; and adjusting the location of the gripper based on the attitude. The method may also comprise comparing a signal strength of a pod alignment sensor in the material handling system with a predetermined signal strength and presenting an alert when the gripper is outside an alignment tolerance zone.

The method may also include sensing a location of an alignment feature on the transport carrier which comprises linearly moving a sensor on the gripper over the alignment feature, sensing a location of an alignment feature on the transport carrier which comprises tracing a circumference of the alignment feature with a sensor on the gripper and sensing a location of an alignment feature on the transport carrier which comprises moving a sensor on the gripper over the alignment feature in an arcurate pattern.

The method also includes sensing an edge of a flange of the gripper on the transport carrier and rotationally aligning the gripper with the gripper flange such that the gripper is juxtaposed to the edge of the gripper. The method also includes calculating a distance to move the gripper based on the attitude of the gripper and storing the attitude of the gripper in a memory of the automated material handling system.

Another aspect of the disclosure provides a semiconductor processing system comprising at least one processing tool; a transport section configured to transport carriers to and from the processing tool; and a transport vehicle movably mounted on the transport section; wherein the transport vehicle is configured to: sense a location of a transport carrier alignment feature; adjust a location of a transport vehicle gripper based on the location of the transport carrier alignment feature; sense an attitude of the gripper at a point of engagement with the transport carrier; and adjust the location of the gripper based on the attitude of the gripper. The transport vehicle comprises a pod alignment feature having a pod alignment sensor. The pod alignment sensor comprises a capacitive sensor. The transport vehicle comprises a gripper member having a lower portion pivotally mounted to an upper portion of the gripper member; and at least one attitude sensor mounted between the upper portion and the lower portion, the attitude sensor configured to sense a displacement of the lower portion relative to the upper portion.

Another aspect of the disclosure provides a carrier transport system comprising: at least one carrier; and a transport vehicle configured to grip and to transport the at least one carrier; wherein a gripper of the transport vehicle is configured to sense a location of a carrier alignment feature and is further configured to adjust a location of the gripper based on the location of the carrier alignment feature. The gripper comprises a pod alignment feature having a pod alignment sensor. The pod alignment sensor comprises a capacitive sensor.

Another aspect of the disclosure provides a carrier transport system comprising: at least one carrier; and a transport vehicle configured to grip and to transport the at least one carrier; wherein the transport vehicle is configured to sense an attitude of a transport vehicle gripper at a point of engagement with the carrier and is further configured to adjust a location of the transport vehicle gripper based on the attitude of the transport vehicle gripper. The transport vehicle comprises: a gripper module having a lower portion pivotally mounted to an upper portion; and at least one attitude sensor mounted between the upper portion and the lower portion, the attitude sensor configured to sense a displacement of the lower portion relative to the upper portion.

### BRIEF DESCRIPTION OF THE DRAWINGS

The foregoing aspects and other features of the exemplary embodiments are explained in the following description, taken in connection with the accompanying drawings, wherein:

FIG. 1 is an exemplary view of an automated material handling system incorporating features of the exemplary embodiments;

FIG. 2 is an isometric view of a gripper incorporating features of the exemplary embodiments;

FIGS. 3A and 3B are an exemplary illustration of the alignment of a gripper alignment feature in accordance with an exemplary embodiment with an alignment feature on a workpiece carrier;

FIG. 4 is a transport vehicle incorporating features of the exemplary embodiments;

FIG. 5 is an exemplary illustration of the alignment of a gripper in accordance with an exemplary embodiment with a workpiece carrier/load port; and

FIG. 6 is a flow chart of a method for aligning a gripper with a workpiece carrier/load port in accordance with an exemplary embodiment.

### DETAILED DESCRIPTION OF THE EXEMPLARY EMBODIMENTS

Although the present invention will be described with reference to the embodiments shown in the drawings and described below, it should be understood that the present invention can be embodied in many alternate forms of embodiments. In addition, any suitable size, shape or type of elements or materials could be used.

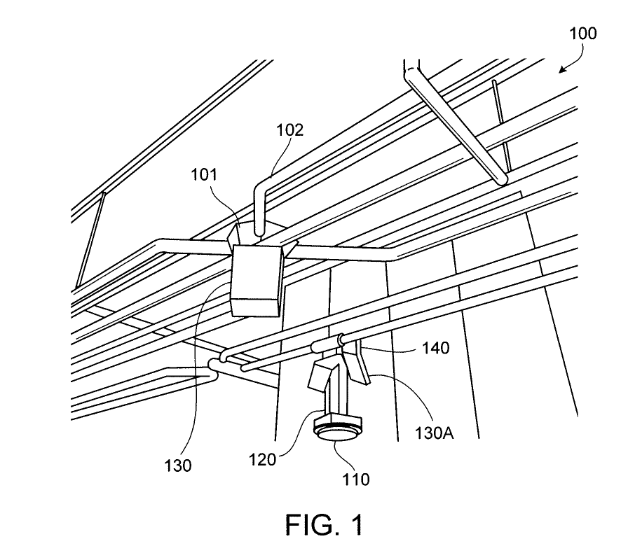

Referring to FIG. 1, a semiconductor automated material handling system (“AMHS”) 100 incorporating features of the exemplary embodiments is shown. As can be seen in this exemplary embodiment, the AMHS 100 may be an overhead hoist transport system. However, the features of the exemplary embodiments can be equally applied to any suitable transport system such as for example, transport systems that support semiconductor carriers from the bottom, the sides or by any other suitable manner.

The AMHS 100 of FIG. 1 may be a vehicle based transport system that includes guideways 102, turntables 101, and transport vehicles 130. In alternate embodiments any suitable transport system may be used. Suitable examples of transport systems that may be adapted to incorporate features of the exemplary embodiments include U.S. patent application Ser. No. 10/393,728 entitled “GROWTH MODEL AUTOMATED MATERIAL HANDLING SYSTEM” and filed on Mar. 21, 2003; U.S. patent application Ser. No. 10/697,528 entitled “AUTOMATED MATERIAL HANDLING SYSTEM” and filed on Oct. 30, 2003; and U.S. patent application Ser. No. 11/211,236 entitled “TRANSPORTATION SYSTEM” and filed on Aug. 24, 2005, the entire contents of each of which are incorporated herein by reference.

FIG. 1 illustrates merely a representative portion of the guideway 102, and the guideway may extend as desired, and have any suitable shape so that the transport paths provided thereby for transport vehicles 130 allow the vehicles access to any desired number of tool stations in any desired locations of the fab for transfer of carriers 110 between the tool station and vehicle. The substrate processing tool at any given tool station may be for example, any desired type such as a fabrication tool (e.g. the GX series tool from Brooks Automation Inc.), a stocker or sorter. The tool may have a casing or enclosure defining an interior space into which substrates (independent of carriers) or the carriers themselves are loaded/unloaded. A suitable example of a tool is disclosed in U.S. patent application Ser. No. 11/210,918 entitled “ELEVATOR-BASED TOOL LOADING AND BUFFERING SYSTEM” and filed on Aug. 23, 2005, which is incorporated by reference herein in its entirety. The carrier 110 may be any suitable type of carrier capable of holding workpieces such as substrates (e.g. 200, 300, 450 mm or any other diameter/size semiconductor wafer, reticle or flat panel for flat panel displays). The carrier 110 may have a casing capable of holding the substrates in a controlled atmosphere. The carrier 110 may be a reduced capacity carrier. Reduced capacity carriers may have a capacity of fewer than the conventional 13 or 25 wafers and may be constructed in a manner similar to the FOUP defined in the SEMI standards, but characterized by reduced height and weight. A suitable example of a substrate carrier is disclosed in U.S. patent application Ser. No. 11/207,231 entitled “REDUCED CAPACITY CARRIER AND METHOD OF USE” and filed on Aug. 19, 2005, which is incorporated herein by reference in its entirety. The carrier may be front (side) opening or bottom opening. In alternate embodiments, the carriers may be any other desired type of carrier as the features of the exemplary embodiments disclosed are equally applicable to transport systems for any kind of workpiece carrier.

The guideways 102 may form a semiconductor workpiece transit system that may allow, for example, a transport vehicle 130 access to any location within a fab facility. The guideways 102 may be joined by, for example, turntables 101 that may allow a transport vehicle to switch from one guideway to another guideway so that, for example, the shortest route between destinations may be realized. In alternate embodiments, the turntables 101 may allow a transport vehicle to switch between a travel lane and a process tool access lane as disclosed in the U.S. patent application entitled “TRANSPORT SYSTEM” referenced above. The guideways 102 may be, for example, hard-coated aluminum monorails with an integrated power delivery system and integrated wire management. In alternate embodiments the guideways 102 may be a bi-directional track system having any suitable power delivery or wire management systems. In other alternate embodiments the guideway may provide the interbay and/or intrabay transport of semiconductor carriers. In still other alternate embodiments the transit system may be trackless with sensors or other suitable guides located on the fab floor that autonomous wheeled vehicles are adapted to follow. The guideways 102 may be assembled from straight sections and/or curved sections of track. These straight and curved sections of track may permit flexibility in the shape and size of the fab layout. The guideways may be provided in various lengths and may be cut to any desired length to fit any suitable fab layout or application.

Transport vehicle stations (not shown) may also be provided on the guideways in, for example, the areas where the transport vehicle 130 may access a load port of, for example, a processing station or any suitable processing equipment such as, for example, a sorter, stocker or carrier storage shelves. A suitable example of carrier storage shelves that may be incorporated with the exemplary embodiments is disclosed in U.S. patent application Ser. No. 10/682,809 entitled “ACCESS TO ONE OR MORE LEVELS OF MATERIAL STORAGE SHELVES BY AN OVERHEAD HOIST TRANSPORT VEHICLE FROM A SINGLE TRACK POSITION” and filed on Oct. 9, 2003, which is incorporated herein by reference in its entirety. The transport vehicle station may, for example, define the stopping location of a carrier 110 such as a pick/place location, and provide a location identification and/or provide power to, for example, the hoist module (not shown in FIG. 1) of the transport vehicle 130. In alternate embodiments, the transport vehicle 130 may stop at any suitable location to interface with semiconductor processing equipment. The transport vehicles 130, as will be described in greater detail below, may be capable of holding semiconductor workpiece carriers 110 and traveling along the guideways 102 of, for example, the AMHS 100. The transport vehicles 130 may move the workpiece carriers along guideways 102 between, for example, processing tools, or between processing tools and stockers (not shown) or between any other suitable combination of processing equipment.

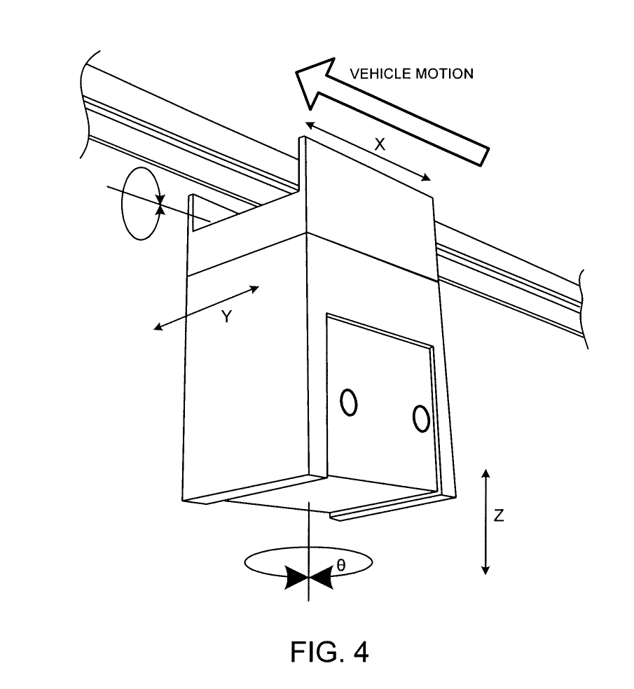

Referring also to FIG. 4, the transport vehicle 130 may generally include a transport module 140, a hoist compensation module 420, a hoist module 410, a gripper module 120 and pivotable pod stabilizer members 130A for stabilizing and preventing movement of the carrier 110 within the transport vehicle 130 while in transport. In alternate embodiments, the transport vehicle 130 may have any suitable configuration. The transport module 140 may include a vehicle controller, a drive assembly and an on-board power supply. In alternate embodiments, the transport module may have any suitable configuration. The vehicle controller may generally control transport vehicle actions and may itself be under the control of, for example, the AMHS controller. The vehicle controller may for example, control the main drive, the hoist or Z-axis, the Y-axis compensation, the gripper motor, onboard sensors and/or communication between, for example, the transport 130 and any suitable processing equipment.

The drive assembly may be a drive wheel/idler wheel assembly having, for example, a DC servomotor that may drive a drive wheel that may be in contact with the guideway. The idler wheels may contact the guideway to support and stabilize the vehicle during transport. In alternate embodiments the drive assembly may be any suitable drive assembly such as, for example, a linear induction drive. An encoder or any other suitable tracking device may also be connected to the drive assembly to track, for example, the position of the transport vehicle 130 along the guideway 102.

The hoist compensation module 420 may be adapted to allow the transport vehicle 130 to adjust, for example, its Y-axis position to properly pick and place carriers 110 at for example, a load port. The hoist compensation module may have, for example, a DC servomotor or any other suitable motor for adjusting the hoist position. An encoder or any other suitable tracking device may also be connected to the motor to track, for example, the Y-axis position of the transport vehicle 130. As can be seen in FIG. 4, for exemplary purposes, the Y-axis may be perpendicular to the direction of the vehicle motion along the guideway while, for example, the X-axis may be along the direction of motion provided by the guideway 102 itself. Adjustment along the X-axis may be provided by the vehicle drive assembly in the transport module 140. In alternate embodiments any suitable drive and/or adjustment systems may be used to adjust the position of the transport vehicle to pick and place carriers.

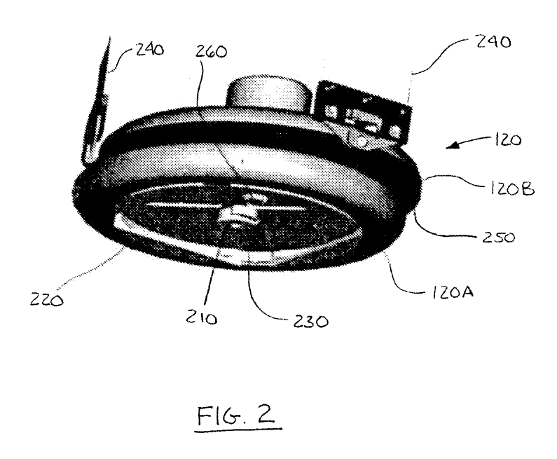

The hoist module 410 may include, for example, a hoist drive assembly (not shown) and support bands 240 (shown in FIG. 2) which may support the gripper module 120. The hoist drive assembly may include, for example, a DC servomotor or any other suitable motor for extending and retracting, for example, the support bands 240. An encoder or any other suitable tracking device may be connected to the motor to track, for example, the Z-axis position of the gripper as it is raised and lowered by the hoist module 410. In alternate embodiments, the gripper may move along any suitable axis, such as for example a horizontal or vertical axis. The support bands 240 may be attached to drive pulleys that may be driven by the hoist drive motor. Any suitable number of support bands 240 may be used to support the gripper module 120. In alternate embodiments, any suitable support system may be used for supporting the gripper module 120. In alternate embodiments the gripper module may be raised and lowered to grip the carrier 110 from the bottom. In still other alternate embodiments the gripper may grip the carrier 110 from one or more sides of the carrier. As may be realized, in one exemplary embodiment the bands may be driven together, while in other exemplary embodiments each band may be individually driven by one or more motors.

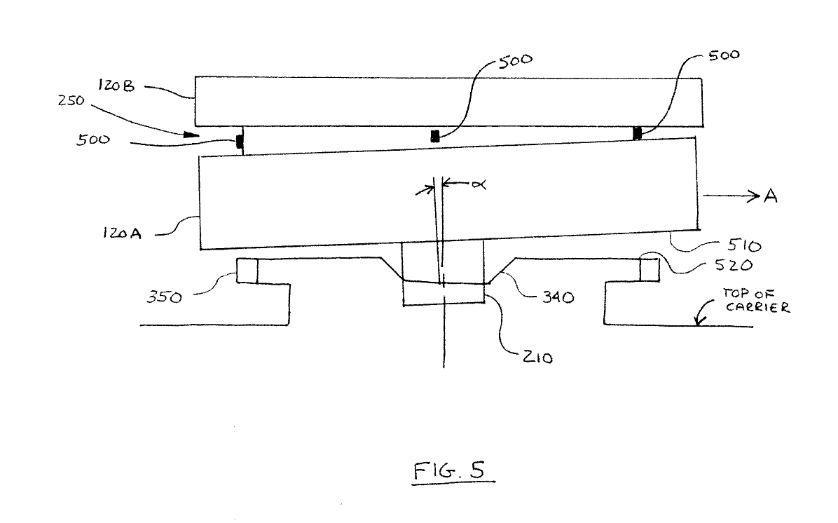

Referring to FIGS. 2 and 5, the gripper module 120 may have an upper and lower portion 120B, 120A respectively. The upper portion 120B may generally include, for example, a rotational drive (not shown) and the connection points for a gripper support system such as the support bands 240. The lower portion 120A may generally include, for example, payload sensor switches 260, a pod alignment feature 210, a pod alignment sensor 230 and a grip ring 220. Grip module attitude sensors 500, which will be described in more detail below, may be located in an area 250 between the upper and lower portions 120B, 120A of the gripper module 120. The rotational drive may be, for example, a DC servomotor or any other suitable motor such as a stepper motor. An encoder or any other suitable tracking device may be attached to the motor so that, for example, the rotational or theta position of the gripper may be tracked. The rotational axis of the gripper (shown in FIG. 4 as 0) may allow the gripper to rotate, for example, to account for load port/carrier rotational misalignment.

The payload sensor switches 260 may sense, for example, that the payload or carrier 110 is properly seated in the gripper before hoisting is attempted. If proper seating of the payload is not sensed, the hoisting operation may be halted and the transport vehicle controller or the AMHS controller may present an audible or visual alert to an operator indicating a problem with the specified transport vehicle. Though, in this exemplary embodiment, one payload sensor switch is shown (FIG. 2), in alternate embodiments any number of payload sensor switches may be employed to sense whether the carrier 110 is properly seated in the gripper.

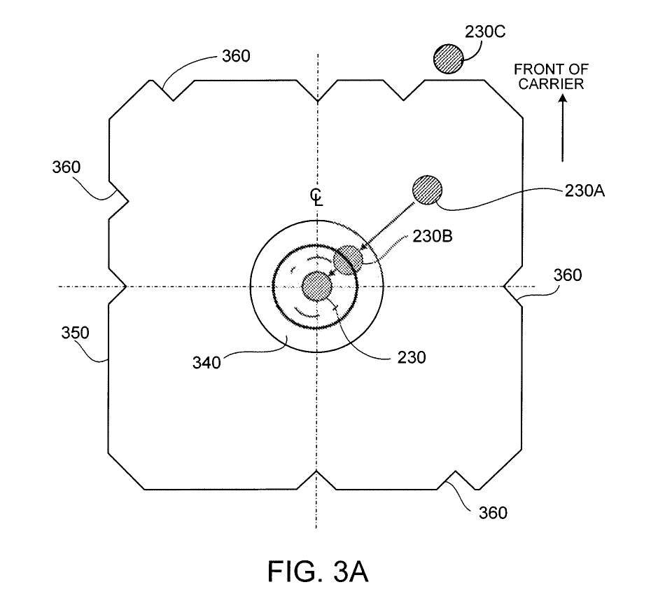

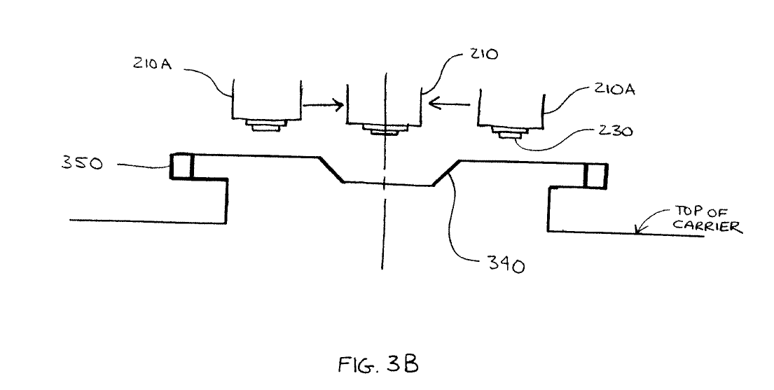

The pod alignment sensor 230 may be located, for example, on the pod alignment feature and will be described in greater detail below. The pod alignment sensor may be for example, a capacitance sensor or any other suitable sensor for detecting any suitable feature of the carrier 110 or load port. In this exemplary embodiment one pod alignment sensor is located on the pod alignment feature, however in alternate embodiments any suitable number of pod alignment sensors may be used. In still other alternate embodiments, the pod alignment sensor may be located in any suitable location on the gripper. The pod alignment feature may engage, for example, an alignment hole 340 (FIGS. 3A and 3B) in the robotic handling flange 350 (FIGS. 3A and 3B) to align the gripper 120 to the flange 350. In this exemplary embodiment the robotic handling flange may be located on the top of the carrier 110 however, in alternate embodiments the robotic handling flange may be located on any suitable side of the carrier. Also in alternate embodiments, the pod alignment sensor may be configured to sense any suitable feature of the carrier. The grip ring 220 may grip the robotic handling flange 350 allowing the carrier 110 to be hoisted into the transport vehicle 130 as will be described in greater detail below.

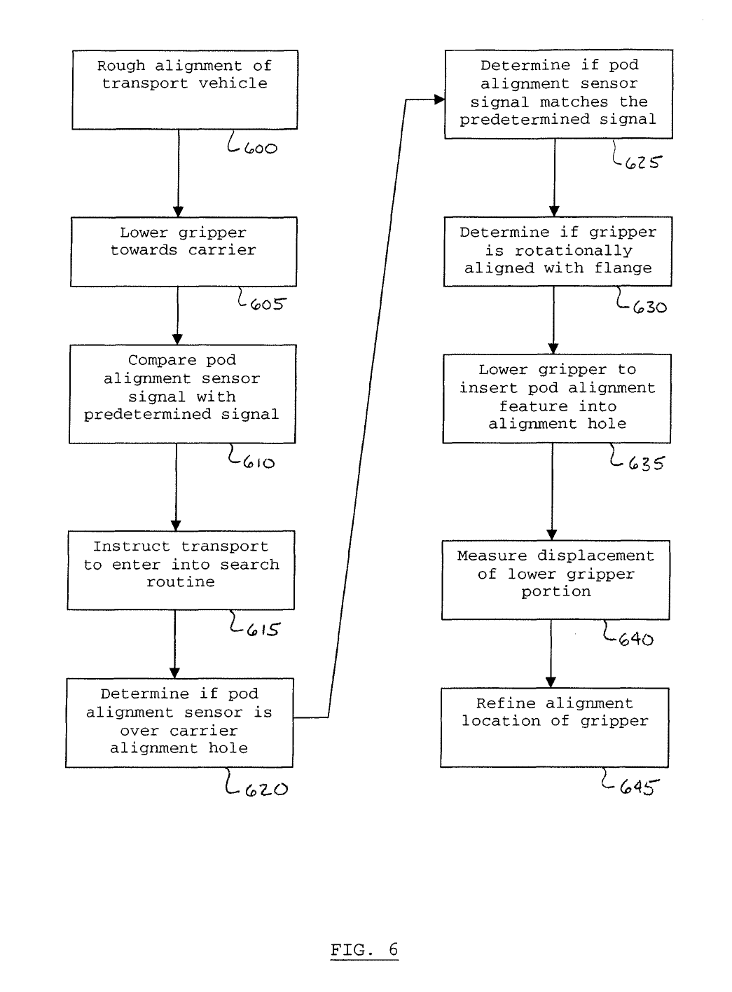

Referring to FIGS. 3A, 3B, 5 and 6, the operation of aligning the transport vehicle 130 with a load port/workpiece carrier 110 in accordance with an exemplary embodiment will be described. During installation of the AMHS 100 of the exemplary embodiments an operator may roughly align the transport vehicle 130 with, for example a load port or other carrier 110 storage location (Block 600, FIG. 6). The rough alignment may be performed with for example, a laser that may be located onboard the transport 130 or the carrier 110. The laser may be configured to illuminate a respective area of the transport or carrier. In alternate embodiments, rough alignment may be performed generally by the eye of the operator or by any suitable rough alignment method. The rough alignment may place the transport vehicle 130 in the general vicinity above the carrier 110. In this exemplary embodiment a carrier 110 may be located on the load port and may be used for the alignment procedure. In alternate embodiments, any suitable feature of the load port itself may be used for the alignment procedure.

The operator may put the transport 130 into an auto-teach or self alignment mode using, for example, a control pendent or any other suitable control pad or operator interface that may be in communication with the AMHS and/or transport controllers. Program code that may be stored within a memory of, for example, the AMHS controller and adapted to execute the auto-teach operation may communicate with and issue alignment commands to the controllers. In alternate embodiments, program code may be stored in a memory of the transport controller for executing the self alignment operation.

The self alignment operation may have, for example, an initial alignment stage performed with the pod alignment sensor 230 and/or a refinement stage using the attitude sensors 500 as will be described below. The pod stabilizers 130A may pivot to an open position as shown in FIG. 1. The gripper 120 may be lowered or moved toward the workpiece carrier 110 (Block 605, FIG. 6). In this exemplary embodiment, the gripper may be lowered to, for example, a predetermined distance that may be calculated during the installation of the AMHS so that it is in close proximity to the carrier 110. In alternate embodiments the gripper 120 may be moved towards the carrier 110 to a point where, for example, the pod alignment sensor 230 or any other suitable onboard sensor begins to generate a signal indicating that the gripper 120 is in proximity to the carrier 110 (e.g. the pod alignment sensor 230 is in proximity to the robotic handling flange 350 of the carrier). In this exemplary embodiment, if the gripper is lowered in a location (as seen in FIG. 3A and indicated by the identifier 230C) where the pod alignment sensor indicates, for example, a null signal, the gripper may be located away from the carrier 110 or outside a self alignment tolerance zone. The self alignment tolerance zone may be defined and stored in for example, a memory of the AMHS controller prior to the auto-teach process. The self alignment tolerance zone may be, for example, the area of the robotic handling flange or any other suitable area. In this exemplary embodiment, the AMHS controller may present an alert signal to the operator to indicate that the gripper 120 is not located over the carrier 110 and/or not within the self alignment tolerance zone. The operator may, for example, perform a rough alignment or a repositioning of the carrier on the load port in response to the alert signal.

A signal strength of the pod alignment sensor 230 may be calculated prior to the self alignment operation and may be stored in a memory of the AMHS controller. In alternate embodiments, this predetermined signal strength may be stored in any suitable location. In this exemplary embodiment, the predetermined signal strength may, for example, correspond to when the pod alignment sensor 230 is centered over the robotic handling flange alignment hole 340 as can be seen in FIGS. 3A and 3B (indicated by the identifiers 230, 210). In alternate embodiments, the signal strength may correspond to any suitable location. When the gripper 120 is in proximity to the carrier 110 and the pod alignment feature 210 is in proximity to the robotic handling flange 350 of the carrier 110, the pod alignment sensor 230 may transmit a signal of a certain strength to the transport controller. This signal may be relayed to the AMHS controller where it may be compared to the predetermined signal strength that may be stored in a memory of the AMHS controller (Block 610, FIG. 6). For example, if the gripper 120 is lowered toward the carrier 110 so that the pod alignment sensor 230 is located over a side portion of the robotic handling flange 350 (as shown in FIGS. 3A and 3B and indicated by the identifier 210A, 230A), the alignment sensor 230 may transmit a peak or high strength signal which when compared to the predetermined signal strength may indicate that the pod alignment feature is over a side portion of the flange 350. As will be described below, the alignment sensor 230 may transmit a weaker signal as the sensor 230 nears the center of the alignment hole 340.

The AMHS controller may instruct the transport 130 to enter into, for example, a “search” routine in which the transport may activate, for example, its X-axis and Y-axis drives (Block 615, FIG. 6) in such a manner as to locate, for example, the alignment hole 340. This activation of the X-axis and Y-axis drives may be done in a manner such that the gripper moves, for example, in an outward spiral pattern beginning with small circles that increase in diameter. In alternate embodiments any suitable search pattern may be used such as for example, a grid type pattern. During the “search” routine and at other times during the auto-teach process, the AMHS controller may continually monitor the signal strength transmitted by the pod alignment sensor 230 and compare it to the predetermined signal strength. During the search, for example, the gripper may continue to move in the search pattern to a point where the pod alignment sensor 230 transmits a lesser strength signal that may indicate that the pod alignment feature is no longer over a side portion of the robotic handling flange 350. The AMHS controller may, for example, instruct the transport 130 to move along its individual axes to determine whether the decreased signal transmitted by the pod alignment sensor 230 may be due to the sensor 230 being located over the alignment hole 340 or whether the sensor 230 may be located away from the robotic handling flange 350 (Block 620, FIG. 6). In the latter case, the AMHS controller may present an alert signal to the operator to indicate that the gripper 120 is not located in an area over the carrier 110 and/or that the gripper 120 is not within the self alignment tolerance zone. The self alignment tolerance zone may be, for example, the area of the robotic handling flange 350. In alternate embodiments, the tolerance zone may be any suitable area. The alert signal may be given through, for example, a display panel connected to the transport or AMHS controller or through an audio and/or visual queue such as a siren and/or a flashing light.

In the former case, where the sensor 230 is located off-center but over the alignment hole 340 (as can be seen in FIG. 3A and indicated by identifier 230B), the AMHS controller may, for example, instruct the transport 130 to move along, for example, its X and Y axes in a linear or non-linear fashion until the sensor 230 transmits a signal that matches the predetermined signal strength that may be stored in the AMHS controller (Block 625, FIG. 6). If, for example, the signal strength transmitted from sensor 230 increases, the sensor 230 may be moving further away from the alignment hole 340. To the contrary, as the signal strength transmitted by the sensor 230 approaches the predetermined signal strength, the sensor may be moving closer to the center of the alignment hole 340. The pod alignment feature 210 and thus the gripper 120 may be centered over the alignment hole 340 when the signal strength transmitted by the sensor 230 matches the predetermined signal strength. In alternate embodiments, the sensor 230 may detect, for example, an edge of the alignment hole 340 and travel around that edge to determine the circumference and coordinate location of the alignment hole 340. Program code stored within the transport controller or the AMHS controller may, for example, compute the center of the hole 340, using coordinates obtained from the transport drive encoders pertaining to the alignment hole circumference. The location of the gripper may be adjusted accordingly so that the pod alignment feature 210 of the gripper 120 may be centered over the alignment hole 340. In still other alternate embodiments, the sensor 230 may be located in any suitable position on the gripper 120 for detecting any suitable feature of the carrier 110.

The AMHS controller, the transport controller or any other suitable controller, may instruct sensors (not shown) that may be located on the gripper in an area proximate the grip ring 220 to scan the robotic handling flange 350 to determine if the gripper 120 is rotationally aligned with the flange 350 (Block 630, FIG. 6). The sensors may be optical sensors, inductive sensors, capacitive sensors or any other suitable sensors. The sensors may detect, for example, an edge of the flange 350 or one or a combination of the alignment notches 360 of the flange 350. In alternate embodiments, the sensors may detect any suitable features. The AMHS controller may, for example, instruct the transport 130 to activate the gripper rotational drive so that the gripper 120 is rotated in either a clockwise or counterclockwise direction (i.e. the theta angle (θ) is adjusted) so that the gripper 120 is rotationally aligned with the flange 340. The adjusted and aligned orientation of the gripper or the theta angle (θ) may be stored in a memory of the transport 130 or the AMHS 100 or any other suitable memory and associated with, for example, its respective transport vehicle station or load port. In alternate embodiments, the gripper 120 may be rotationally aligned with the flange 340 at any point in the auto-teach process.

In this exemplary embodiment, the gripper may be lowered so that the pod alignment feature 210 is inserted into the alignment hole 340 (Block 635, FIG. 6). As can be seen in FIG. 5, the lower portion of the gripper 120A may be pivotable about the upper portion of the gripper 120B. This pivotal mounting may, for example, allow for the insertion of the pod alignment feature 210 into the alignment hole 340 when, for example, there is residual misalignment between the gripper 120 and the carrier 110 resulting from the initial alignment.

To further refine the alignment between the gripper 120 and the carrier 110, attitude sensors 500 may be placed in the area 250 between the upper and lower portions 120B, 120A of the gripper 120. In alternate embodiments, the sensors 500 may be located in any suitable position on the gripper 120. The attitude sensors 500 may be laser sensors, capacitive sensors, inductive sensors, variable reluctance sensors or any other suitable sensors. These attitude sensors 500 may, for example, measure the displacement, velocity, acceleration or other higher order derivatives of the lower portion 120A of the gripper 120 relative to the upper portion 120B. The displacement, velocity and acceleration, for example, may occur from the mechanical interaction between the carrier 110 and the gripper 120 during payload or carrier 110 engagement (Block 640, FIG. 6). The measurements taken by the attitude sensors 500 may be along any relevant axis and used to infer differences between the existing alignment location (i.e. the alignment location obtained during the initial alignment using the pod alignment sensor 230) and an optimal alignment location.

For example, as shown in FIG. 5, the pod alignment feature 210 may be inserted into the alignment hole 340 of the robotic handling flange 350. Due to residual misalignment, the lower portion 120A of the gripper 120 may pivot to an angle α about the upper portion 120B of the gripper 120 during insertion. In this embodiment, the lower portion 120A of the gripper 120 may be freely pivotable about the upper portion 120B. The attitude sensors 500 may detect, for example, the displacement between the upper and lower portions 120B, 120A of the gripper 120 and relay this information to, for example, the transport or AMHS controller. Program code stored within, for example, the AMHS controller may use this displacement information to calculate, for example, the angle α and extrapolate the distance and direction that the gripper 120 is to move so that the upper and lower portions 120B, 120A of the gripper 120 are in line or parallel to each other (i.e. α is equal to or approaching zero)(Block 645, FIG. 6). As may be realized, the gripper may be centered over the alignment hole 340 when the angle α is equal to or approaching zero. In alternate embodiments, the data transmitted by the attitude sensors 500 may be used in any suitable manner to calculate the distance and direction the gripper 120 is to be moved.

As shown in FIG. 5, the gripper 120 may move in the direction of arrow A so that the upper and lower portions 120B, 120A of the gripper 120 are in line or parallel and α is equal to or approaching zero. The attitude sensors 500 may continue to relay measurements to, for example, the AMHS controller as the pod alignment feature 210 is inserted further into the alignment hole 340. The AMHS controller may continually calculate the distance and direction the gripper is to move so that the pod alignment feature 210 can be inserted into the alignment hole 340 without any angular deviation α of the lower portion 120A relative to the upper portion 120B of the gripper 120. When the angular deviation α or the displacement measurements taken by the attitude sensors 500 are minimal or within a predetermined tolerance the gripper 120 may be at its optimal alignment with, for example, the carrier 110 or load port. The optimal alignment position of the gripper 120 may be stored in a memory of the transport 130 or the AMHS 100 and associated with, for example, a respective transport vehicle station or load port as will be described below. Because the gripper 120 and the carrier 110 are at an optimal alignment, wear on both the gripper 120 and the carrier 110 may be minimized due to decreased frictional forces and any binding that may occur during, for example, the mating of the gripper 120 and the carrier 110 or when the grip ring 220 grips the flange 350.

Although three attitude sensors 500 are shown in FIG. 5, in alternate embodiments, any number of attitude sensors 500 may be used to measure, for example, the displacement of any portion of the gripper 120. In other alternate embodiments, the attitude sensors 500 may be used while the fab is in operation, rather than in an auto-teach mode, so that the optimal alignment location for each processing station load port may be continually or periodically monitored and/or adjusted. In still other alternate embodiments, the lower portion 120A of the gripper 120 may be motorized in that the pivot angle of the lower portion 120A of the gripper 120 with respect to the upper portion 120B may be controllable. For example, where the gripper and the carrier are not parallel within, for example, a specified tolerance (e.g. the load port is not level or the guideway is not level) the lower portion 120A of the gripper 120 may be adjusted with the motor so that a surface 510 of the gripper 120 is parallel with a surface 520 of the robotic handling flange 350. The gripper 120 and thus the pod alignment feature 210 may be inserted angularly into the alignment hole 340 by energizing any combination of the transport vehicle drive motors so that minimal friction and wear occurs during mating of the gripper 120 and the carrier 110.

The optimal alignment location of the gripper may be stored in a memory of, for example, the AMHS controller and may be associated with, for example, its respective transport vehicle station. This optimal alignment data may be used by other transport vehicles to calculate their respective optimal alignment offsets for a given transport vehicle station or load port. In alternate embodiments, each transport vehicle may be taught its optimal alignment for each transport station within the fab. The optimal alignment data for each transport and/or vehicle station may be stored in, for example, a matrix within the AMHS controller memory. In alternate embodiments, the optimal alignment data may be stored in any suitable memory location.

In operation, each transport vehicle 130 may position itself at its optimal alignment position (about all axes of motion) before lowering the gripper module 120 at, for example, any given load port. The capturing and releasing of the carrier 110 with the gripper 120 may be performed at an increased speed due to the precise alignment between the gripper 120 and the carrier 110 thereby increasing the throughput and production of the semiconductor workpieces. The optimal alignment may permit, for example, the mating parts of the gripper 120 and the carrier 110 to interact with minimal contact so that the drive speeds of the hoist do not have to be decreased upon, for example, insertion of the pod alignment feature 210 into the alignment hole 340. In addition, the exemplary embodiments described above decrease the AMHS and load port setup time to further increase productivity of the fab in that there are no external sensors or fixtures to set up or take down as with convention automated material handling systems.

It should be understood that the foregoing description is only illustrative of the exemplary embodiments. Various alternatives and modifications can be devised by those skilled in the art without departing from the invention. Accordingly, the exemplary embodiments are intended to embrace all such alternatives, modifications and variances which fall within the scope of the appended claims.

What is claimed is:

1. A method of performing alignment in a material handling system, the method comprising:
moving a gripper of a transport vehicle towards to a transport carrier;
sensing a location of an alignment feature on the transport carrier;
adjusting a location of the gripper based on the location of the alignment feature; and
storing the location of the gripper in a memory of the automated material handling system.

2. The method of claim 1, further comprising:
sensing an attitude of the gripper at a point of engagement between the gripper and the transport carrier; and
adjusting the location of the gripper based on the attitude.

3. The method of claim 1, further comprising comparing a signal strength of a pod alignment sensor in the material handling system with a predetermined signal strength.

4. The method of claim 1, further comprising presenting an alert when the gripper is outside an alignment tolerance zone.

5. The method of claim 1, wherein sensing a location of an alignment feature on the transport carrier comprises linearly moving a sensor on the gripper over the alignment feature.

6. The method of claim 1, wherein sensing a location of an alignment feature on the transport carrier comprises tracing a circumference of the alignment feature with a sensor on the gripper.

7. The method of claim 1, wherein sensing a location of an alignment feature on the transport carrier comprises moving a sensor on the gripper over the alignment feature in an arcurate pattern.

8. The method of claim 1, further comprising sensing an edge of a flange of the gripper on the transport carrier.

9. The method of claim 8, further comprising rotationally aligning the gripper with the gripper flange such that the gripper is juxtaposed to the edge of the gripper.

10. The method of claim 2, wherein adjusting the location of the gripper comprises calculating a distance to move the gripper based on the attitude of the gripper.

11. The method of claim 2, further comprising storing the attitude of the gripper in a memory of the automated material handling system.

12. A semiconductor processing system comprising:
at least one processing tool;
a transport section configured to transport carriers to and from the processing tool; and
a transport vehicle movably mounted on the transport section;
wherein the transport vehicle is configured to:
sense a location of a transport carrier alignment feature;
adjust a location of a transport vehicle gripper based on the location of the transport carrier alignment feature;
sense an attitude of the gripper at a point of engagement with the transport carrier; and
adjust the location of the gripper based on the attitude of the gripper.

13. The semiconductor processing system of claim 12, wherein the transport vehicle comprises a pod alignment feature having a pod alignment sensor.

14. The semiconductor processing system of claim 13, wherein the pod alignment sensor comprises a capacitive sensor.

15. The semiconductor processing system of claim 12, wherein the transport vehicle comprises:
a gripper member having a lower portion pivotally mounted to an upper portion of the gripper member; and
at least one attitude sensor mounted between the upper portion and the lower portion, the attitude sensor configured to sense a displacement of the lower portion relative to the upper portion.

16. A carrier transport system comprising:
at least one carrier; and
a transport vehicle configured to grip and to transport the at least one carrier;
wherein a gripper of the transport vehicle is configured to sense a location of a carrier alignment feature and is further configured to adjust a location of the gripper based on the location of the carrier alignment feature.

17. The carrier transport system of claim 16, wherein the gripper comprises a pod alignment feature having a pod alignment sensor.

18. The carrier transport system of claim 17, wherein the pod alignment sensor comprises a capacitive sensor.

19. A carrier transport system comprising:
at least one carrier; and
a transport vehicle configured to grip and to transport the at least one carrier;
wherein the transport vehicle is configured to sense an attitude of a transport vehicle gripper at a point of engagement with the carrier and is further configured to adjust a location of the transport vehicle gripper based on the attitude of the transport vehicle gripper.

20. The carrier transport system of claim 19, wherein the transport vehicle comprises:
a gripper module having a lower portion pivotally mounted to an upper portion; and
at least one attitude sensor mounted between the upper portion and the lower portion, the attitude sensor configured to sense a displacement of the lower portion relative to the upper portion.
